(19) United States
(12) Patent Application Publication
(10) Pub. No.: US 2020/0066701 A1
(43) Pub. Date: Feb. 27, 2020

(54) STACKED CHIP PACKAGE HAVING SUBSTRATE INTERPOSER AND WIREBONDS

(71) Applicant: Intel Corporation, Santa Clara, CA (US)

(72) Inventor: Mao GUO, Shanghai (CN)

(21) Appl. No.: 16/326,901

(22) PCT Filed: Sep. 28, 2016
(86) PCT No.: PCT/CN2016/100530

§ 371 Date: Feb. 20, 2019

(51) Int. Cl. H01L 25/18; H01L 23/00; H01L 25/065

(52) U.S. Cl. CPC H01L 25/18; H01L 24/73; H01L 25/0657; H01L 24/49; H01L 2224/73265; H01L 24/19; H01L 2224/48227; H01L 2224/97; H01L 2224/73253; H01L 24/20

(57) ABSTRACT

An apparatus is described that includes a semiconductor chip package. The semiconductor chip package includes a plurality of stacked semiconductor chips. The plurality of stacked semiconductor chips are stacked with a lateral offset, wherein, the lateral offset exposes first wirebond pads of the plurality of stacked semiconductor chips. The semiconductor chip package further includes a substrate interposer having second wirebond pads. The semiconductor chip package further includes wirebonds connecting the first wirebond pads and the second wirebond pads. The semiconductor chip package further includes a package substrate. The semiconductor chip package further includes vias that are electrically connected to the substrate interposer and a first surface of the package substrate. The semiconductor chip package further includes package level I/Os on a second surface of the package substrate that is opposite the first surface of the package substrate.

### FIELD OF INVENTION

The field of invention pertains generally to the semiconductor arts, and, more specifically, to a stacked chip package having a substrate interposer and wirebonds.

### BACKGROUND

The semiconductor arts have traditionally faced the challenge of attempting to integrate electronic functionality into as small a volume as possible. Stacked chip package structures have recently emerged as a popular packaging technology for integrating multiple semiconductor die into a same semiconductor package.

### FIGURES

A better understanding of the present invention can be obtained from the following detailed description in conjunction with the following drawings, in which:

FIG. 1 shows a stacked chip package;

FIGS. 2a and 2b show improved stacked chip packages;

FIGS. 3a through 3j show a process for manufacturing the stacked chip package of FIG. 2a;

FIGS. 4a through 4f show a process for manufacturing the stacked chip package of FIG. 2b;

FIG. 5 shows a method of manufacturing a stacked chip package;

FIG. 6 shows a computing system.

### DETAILED DESCRIPTION

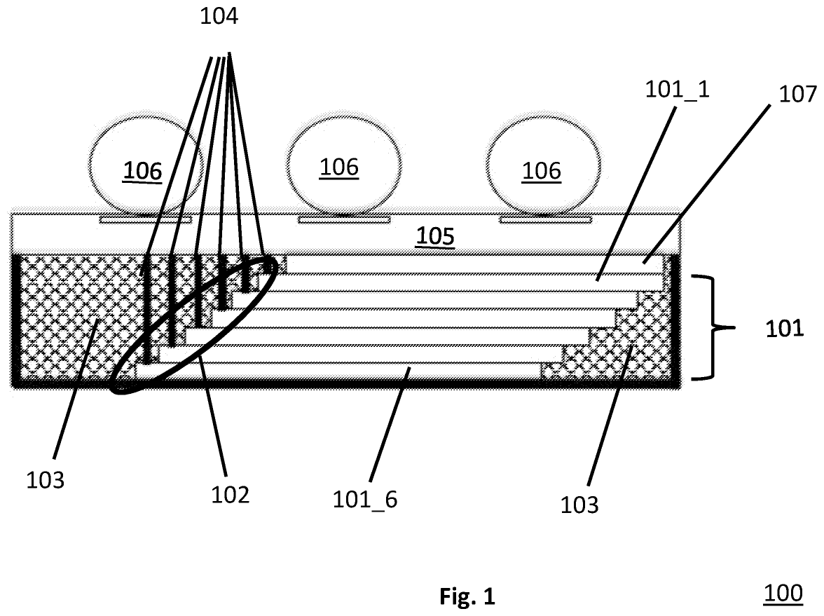

One way to increase the functionality within a semiconductor chip package is to stack multiple semiconductor chips in a single package. FIG. 1 shows an example of a possible structure 100 that includes semiconductor chips 101 stacked at a lateral offset with respect to one another. The stacking with a lateral offset exposes each chip's respective I/Os (e.g., bond pads) on the lateral periphery 102 of each of the semiconductor chips 101. The chips 101 are encapsulated in a mold compound 103.

Owing to the large vertical distance between the “bottom” die 101_6 and a redistribution layer (RDL) 105 layer that acts as a structural platform for the overall package, through mold vias are not used to connect the pad I/Os on the periphery 102 of the stacked chips. That is, extremely deep through mold vias are not really feasible economically and/or technically. As such, the electrical interconnect between the chip I/Os at the periphery 102 of the chips and the RDL layer 105 is formed with vertical wires 104 and not through mold vias.

During manufacture, a spacer 107 (e.g., composed of a silicon die coated with Aluminum) is placed on the stacked dies 101_1 through 101_6. Then, wire bonds are formed from the chip I/Os on the stacked die periphery 102 to the top of the spacer 107. The wire bonds sprout vertically from the periphery 102 of the chips stack to the top of the spacer. The wire bonds, chip stack and spacer 107 are then encompassed in a mold compound with a thickness that exceeds high above the spacer 107 to cover the loops of the wire bonds. The mold compound is then ground down to the surface of the spacer 107 which grinds away the loops of the wire bonds leaving only their vertical sprouts thus forming vertical wires 104.

The particular structure 100 of FIG. 1 therefore has a number of inefficiencies. A first inefficiency is the expense, both time wise, energy wise and wasted material wise, of the aforementioned grinding down process to remove the wire bond loops. Another inefficiency with the proposed structure 100 of FIG. 1 is the presence of the spacer 107 which adds to the vertical profile of the package 100.

Another inefficiency is that the vertical wires 104 do not lend themselves very well to aggressive chip stacking approaches in which the chip stacking laterally “zig-zags” back and forth. For example, as observed in FIG. 1, the lateral offset of the chip stacking progresses to the right. A more aggressive package design that seeks to increase the number of stacked chips without increasing the size of the footprint of the package 100 might be motivated to include another chip stack above the stacked chips of FIG. 1 but whose laterally offset progresses to the left rather than to the right.

Unfortunately, this lateral offset zig-zag approach is not really feasible with the packaging approach of FIG. 1 because the lower stack of chips 101 (that progresses to the right) would act as an obstruction for the vertical wires that would need to connect to the top stack whose lateral offset progresses to the left. As such, aggressive chip stacking that zig-zags the progression of the lateral offset is not feasible with the package design 100 of FIG. 1.

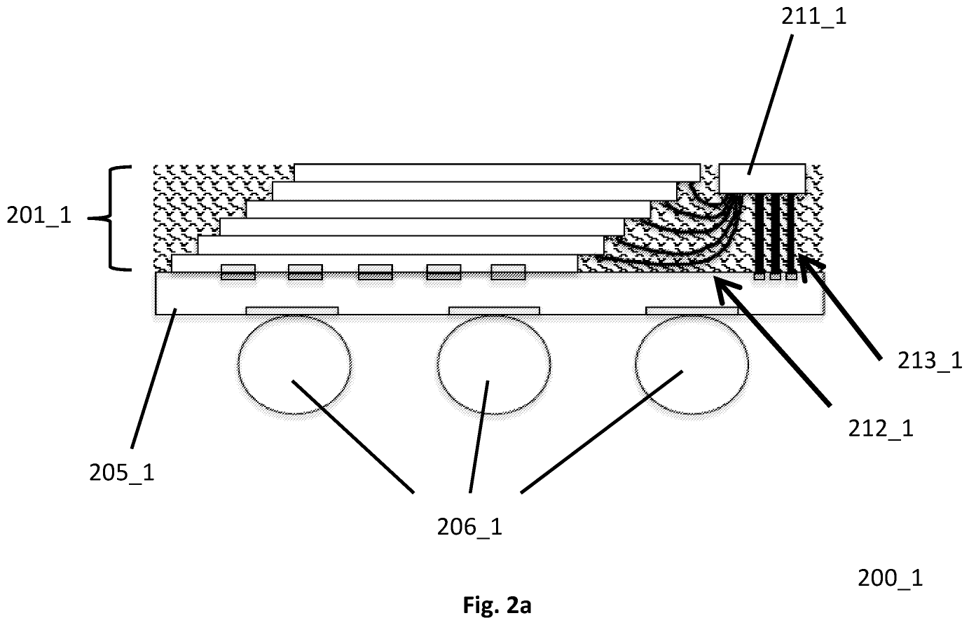

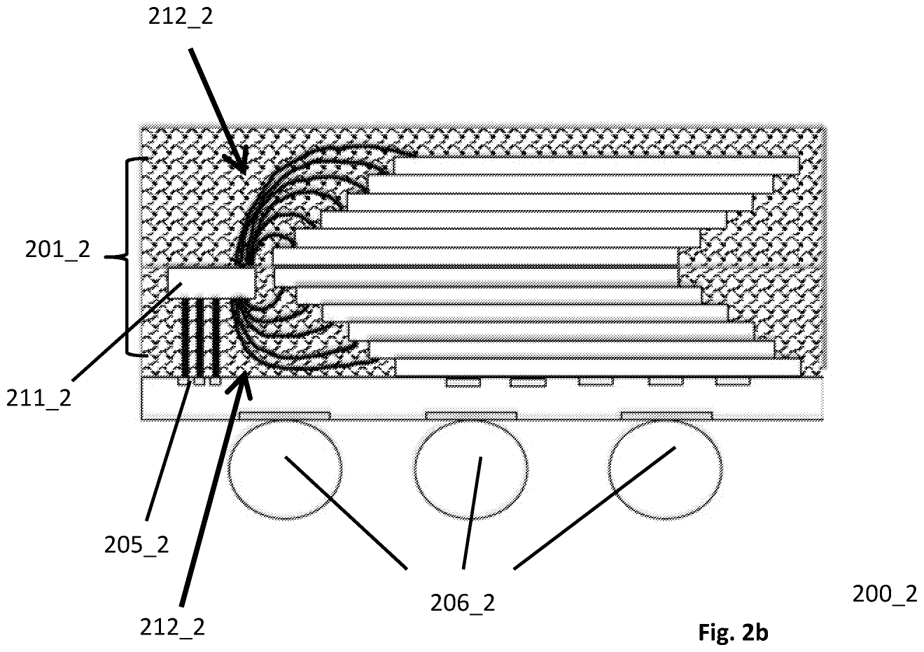

FIGS. 2a and 2b show improved stacked package design approaches 200_1, 200_2 that use a substrate interposer 211_1, 211_2 and wire bonds 212_1, 212_2 to affect the electrical I/O connections between the stacked die 201_1, 201_2 and the RDL 205_1, 205_2. FIG. 2a shows a more modest stacked chip package 200_1 whose semiconductor chips 201_1 have a lateral offset that progresses in only one direction. FIG. 2b, by contrast, shows a more aggressive stacked chip package 200_2 in which the lateral offset of the stacked chips 201_2 zig-zags to the right and then to the left when viewing the stack from a top to bottom direction as depicted in FIG. 2b.

Here, the use of wire bonds 212_1, 212_2 to directly connect to the chips 201_1, 201_2 and an interposer 211_1, 211_2, rather than directly connecting to the chips with vertical wires (as with the approach of FIG. 1), enables easy and cost effective electrical connections between the stacked semiconductor chips 201_1, 201_2 and the RDL 205_1, 205_2. The interposer 211_1, 211_2 collects/coordinates I/O signals/wiring from the stacked chips 201_1, 201_2 and presents corresponding pad I/Os on the surface of the interposer that faces the RDL 205_1, 205_2. The pads on the interposer surface are then electrically connected to facing pads on the RDL 205_1, 205_1 by way of through mold vias 213_1, 213_2.

Additionally, comparing the packages of FIGS. 2a and 2b with the package of FIG. 1, note that the packages of FIGS. 2a and 2b do not include the spacer 107 that the package of FIG. 1 includes. Without the presence of a spacer 107, the packages of FIGS. 2a and 2b should be able to achieve lower vertical height profiles for a same number of stacked chips than the package of FIG. 1.

The packages of FIGS. 2a and 2b are suited for any motivation to stack semiconductor chips. A common motivation is to increase the density of a memory device such as a solid state disk (SSD). Here, the stacked chips may comprise a plurality of memory chips, such as FLASH memory chips. By stacking memory chips, the storage density of the SSD device is greatly improved without a significant z-height increase. Depending on the specific embodiment, all of the stacked chips may be memory devices, or, e.g., all but one of the stacked chips is a memory chip.

In the case of the former (all stacked chips are memory chips), the electrical interface for communicating to the memory chips is exposed at the package level I/Os 206_1, 206_2. That is, for example, if the stacked chips 201_1, 201_2 have same address and data bit lines tied together so that each of the stacked chips 201_1, 201_2 are essentially connected to a same memory bus, the interface for the memory bus itself is exposed at the package level I/Os 206_1, 206_2.

By contrast, in the case of the later (e.g., all but one of the stacked chips 201_1, 201_2 is a memory chip), one of the stacked chips may be a controller chip or other chip directed to performing control related functions internal to the package. For example, in the case of an SSD, the non memory chip may be designed to perform FLASH memory related maintenance tasks such as wear leveling and garbage collection.

The controller may also be designed to handle read/write requests from an external host where the read/write requests from the host are formatted according to a first format (e.g., a Universal Serial Bus (USB) interface, Peripheral Component Interconnect Express (PCIe) interface, etc.) and the internal read/write commands between the memory controller and the memory devices are formatted according to a different format (e.g., a proprietary memory bus). The controller chip may be implemented as a semiconductor chip that executes program code (e.g., firmware) to perform its tasks or may include dedicated hardware logic circuitry to perform its tasks or may include a combination of the circuitry that executes program code and dedicated hardwired logic circuitry.

Apart from mass storage applications, a single package with multiple stacked memory chips as depicted in FIGS. 2a and 2b can be used for system memory (also referred to as main memory) applications rather than mass storage applications. For example, the multiple stacked chips 201_1, 201_2 may be dynamic random access memory (DRAM) semiconductor chips. Here, in the case where all the stacked chips 201_1, 201_2 are stacked DRAM memory chips, the package level I/Os 206_1, 206_2 may present an industry standard system memory interface such as a double data rate (DDR) based system memory interface.

Further still, an emerging non volatile technology may be used for a system memory application. Here, system designers are considering the use of emerging non volatile memory technologies for use as main memory (or a level of main memory in a multi-level main memory). Here, system memory capable of persistent storage has various benefits that traditional non volatile system memory can not entertain.

Emerging non volatile main memory technologies typically have some combination of the following: 1) higher storage densities than DRAM (e.g., by being constructed in three-dimensional (3D) circuit structures (e.g., a crosspoint 3D circuit structure)); 2) lower power consumption densities than DRAM (e.g., because they do not need refreshing); and/or, 3) access latency that is slower than DRAM yet still faster than traditional non-volatile memory technologies such as FLASH. The latter characteristic in particular permits various emerging non volatile memory technologies to be used in a main system memory role rather than a traditional mass storage role (which is the traditional architectural location of non volatile storage).

Examples of emerging non volatile main memory technologies include, to name a few possibilities, a phase change based memory, a three dimensional crosspoint memory, “write-in-place” non volatile main memory devices, memory devices having storage cells composed of chalcogenide, multiple level flash memory, multi-threshold level flash memory, a ferro-electric based memory (e.g., FRAM), a magnetic based memory (e.g., MRAM), a spin transfer torque based memory (e.g., STT-RAM), a resistor based memory (e.g., ReRAM), a Memristor based memory, universal memory, Ge2Sb2Te5 memory, programmable metallization cell memory, amorphous cell memory, Ovshinsky memory, etc. Any of these technologies may be byte addressable or accessible at cache line granularity so as to be implemented as a main/system memory rather than mass storage (which traditionally has block or sector granularity access).

Solutions having stacked emerging non volatile memory chips may include a controller chip as one of the stacked chips to perform various control functions that are unique to the particular technology that the memory chips are composed. For example, the emerging non volatile stacked memory devices may require a special voltage level (or levels) or special maintenance functions such as wear leveling, etc.

Still further in other embodiments the stacked chips 201_1, 201_2 are chips other than memory chips (or just one or a few of the stacked chips are memory chips). Here, any combination of various chips that are desired for a particular application or functionality may be stacked in the package to integrate the function into the package.

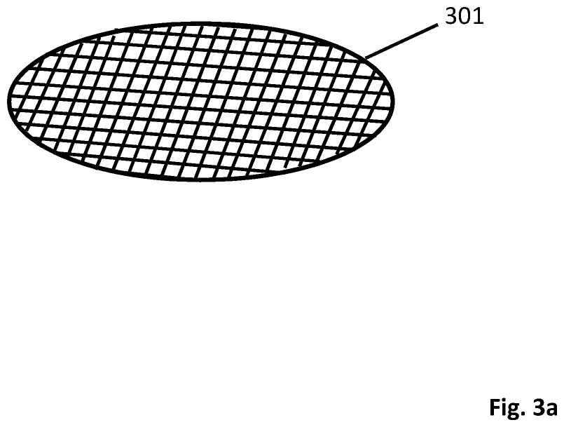

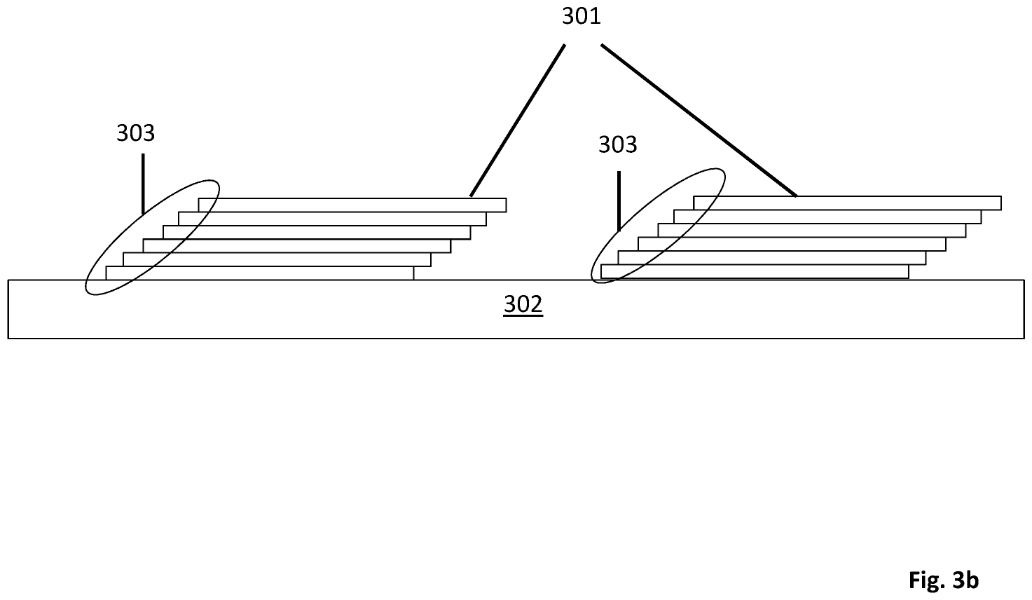

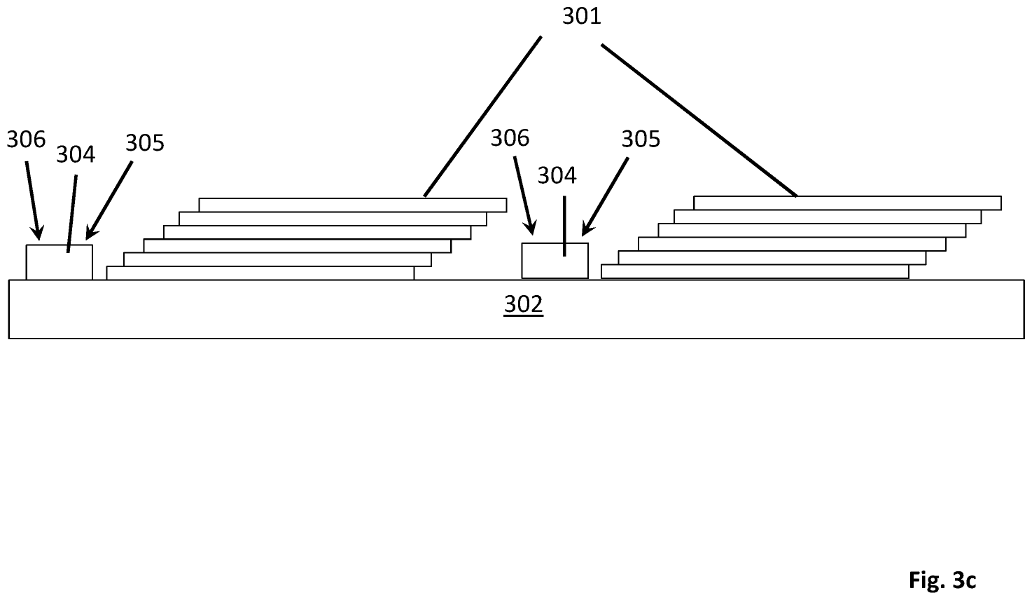

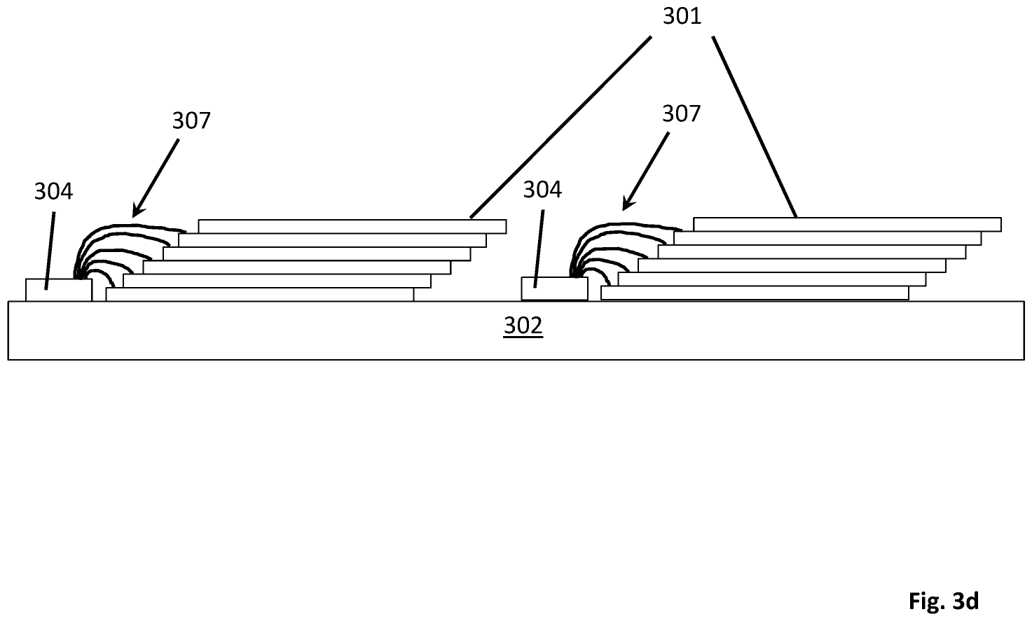

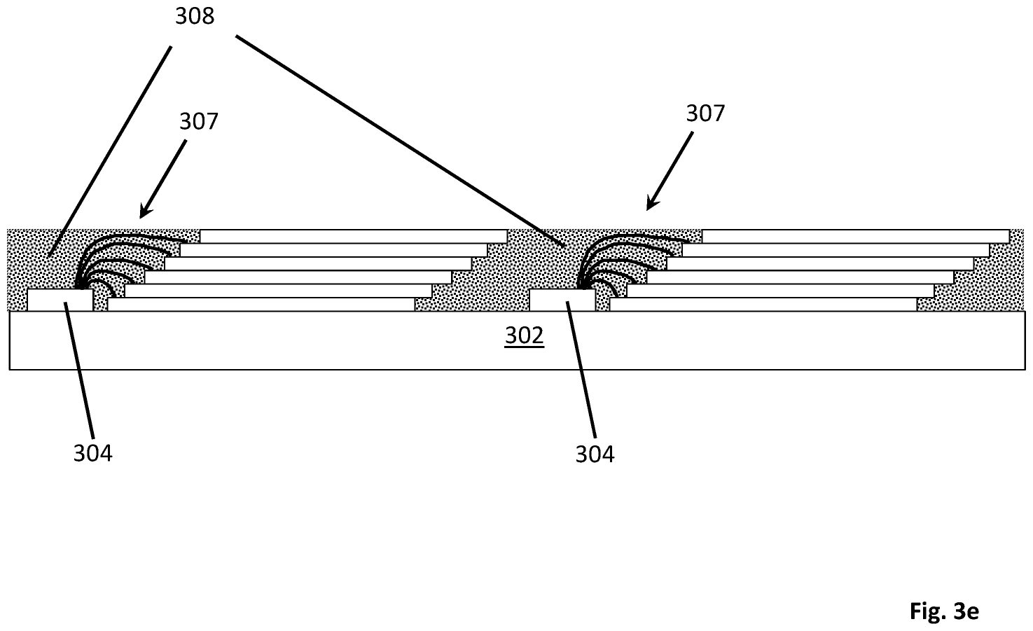

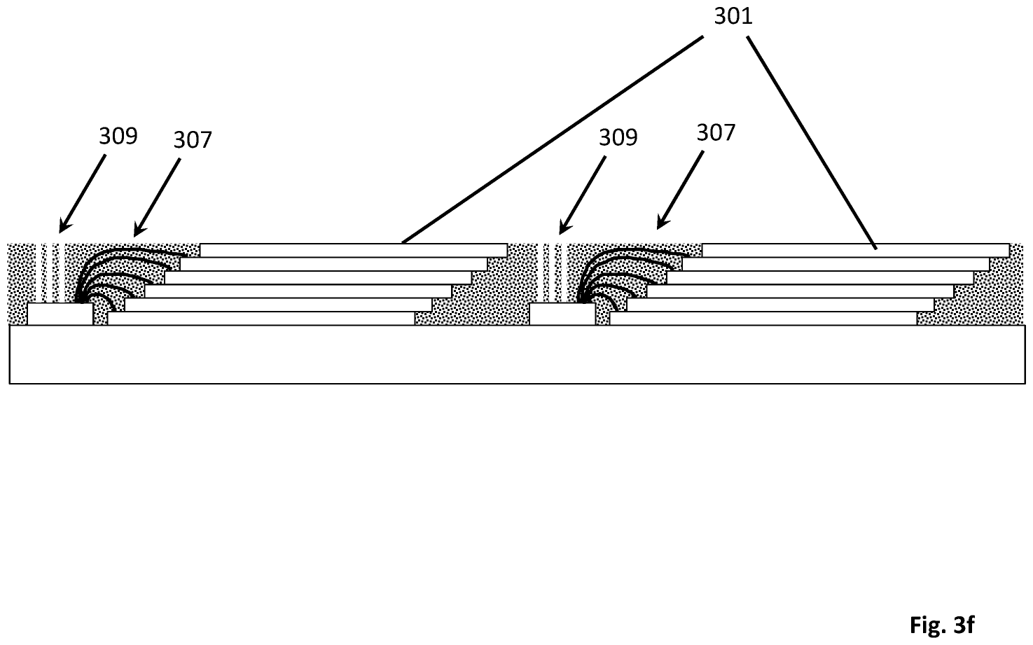

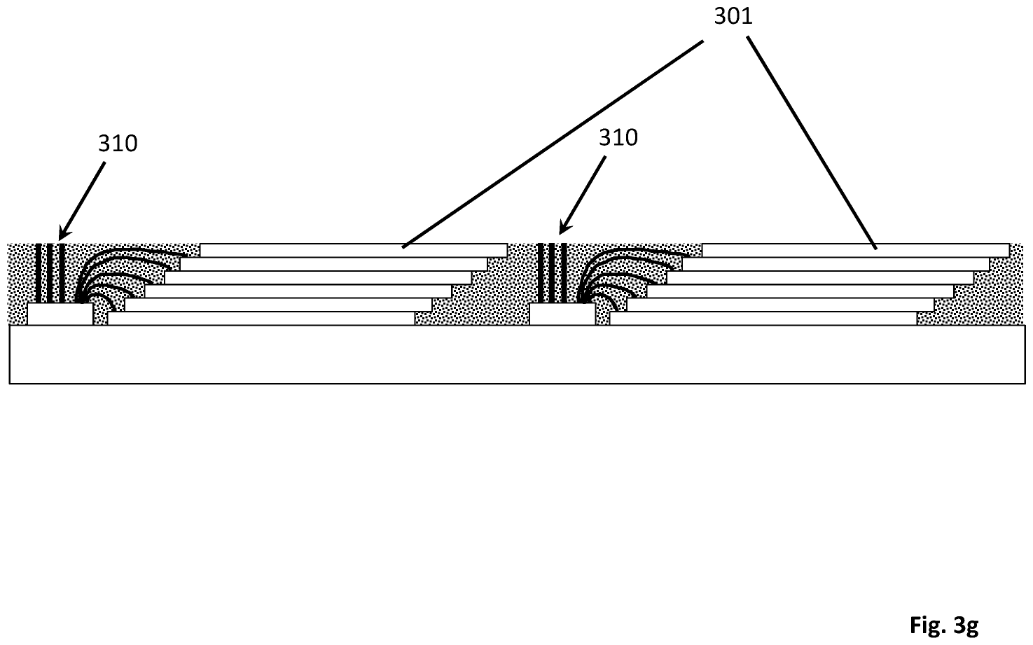

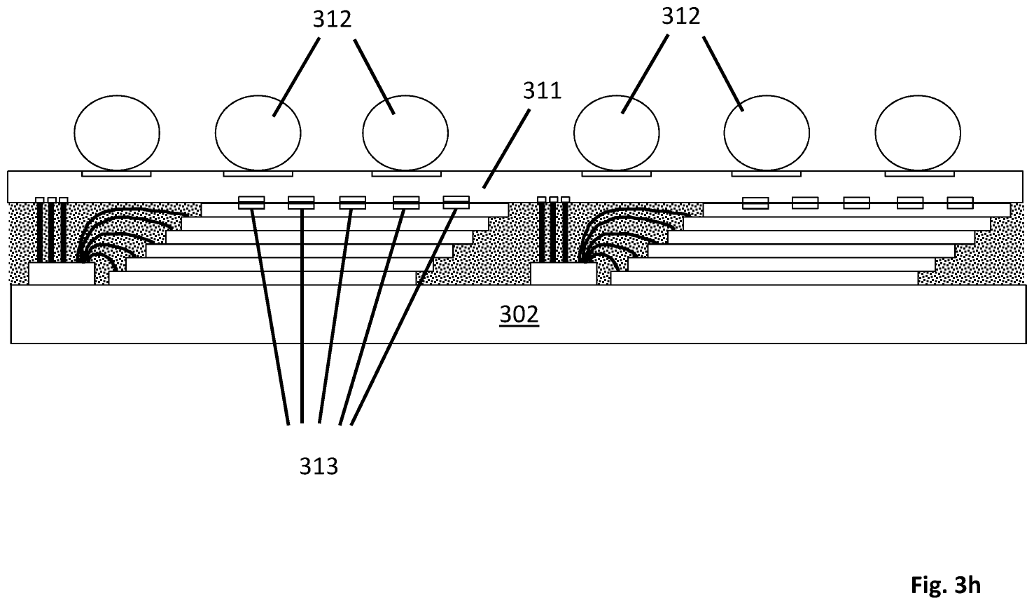

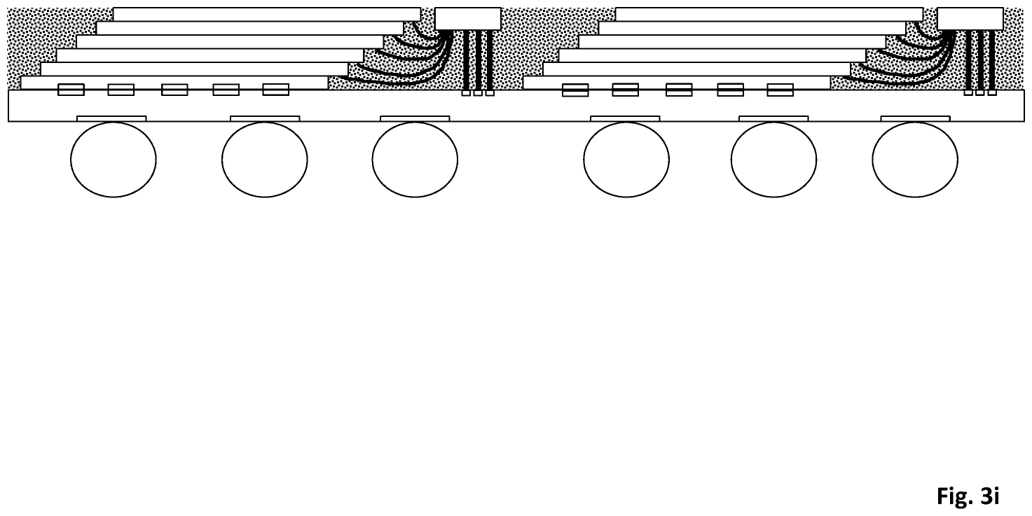

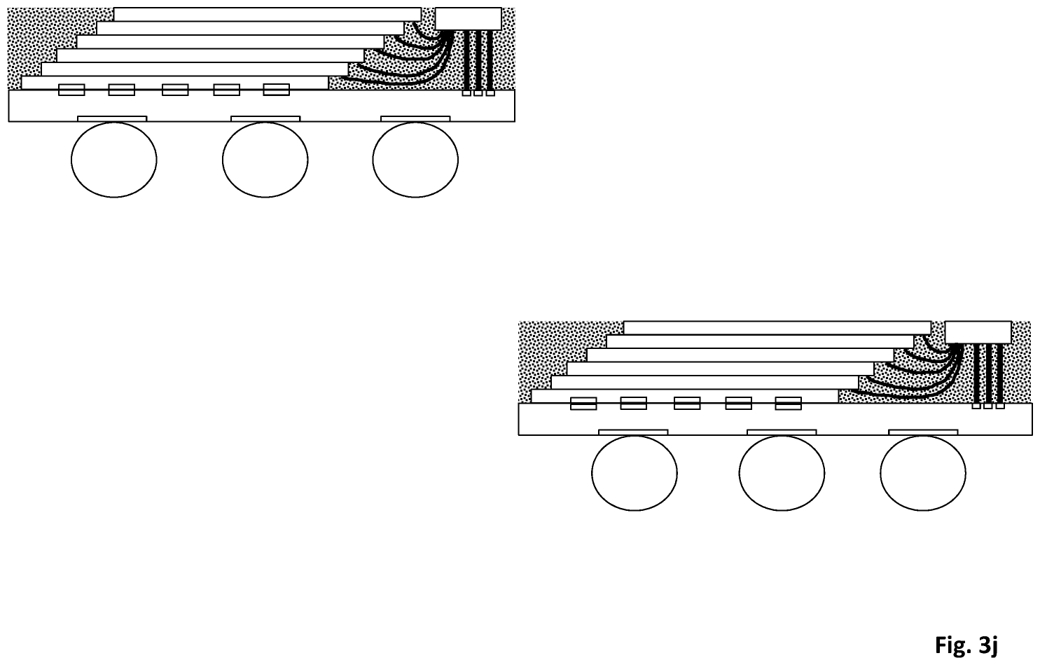

FIGS. 3a through 3j illustrate a process for manufacturing the less aggressive package 200_1 of FIG. 2a. Initially, as observed in FIG. 3a, a semiconductor wafer 301 composed of multiple yet-to-be diced semiconductor chips is manufactured. Here, for instance, the individual chips may be memory chips such as FLASH memory chips. DRAM memory chips or emerging non volatile memory chips. After manufacturing, the wafer 300 is diced to form multiple individual semiconductor chips.

As observed in FIG. 3b, multiple ones of the chips 301 are then stacked on a carrier 302. The carrier 302 may be composed of a panel of some form with a low melting point adhesive, pressure sensitive adhesive or some other easily degradable adhesive on its top surface. The semiconductor chips 301 are then stacked on the carrier 302 with a lateral offset with respect to one another. As observed in FIG. 3b, two semiconductor chip stacks are observed where the lateral offset of both stacks progresses to the right. The manufactured semiconductor chips 301 have wire bond pads on the outer periphery 303 of their exposed upper surface when stacked.

As observed in FIG. 3c a substrate interposer 304 is also placed on the carrier-302. The interposer 302, in one embodiment, is a small multilayered PC board having wire bond pad I/Os 305 on its exposed upper surface and other pad I/Os 306 on the same surface to receive through mold vias yet to be formed. As is known in the art, the PC board may be composed of alternating dielectric layers of any of, e.g., resin, glass fiber, fillers and conductive metal traces (e.g., composed of etched plated copper). The metal traces of different layers may be connected to one another through vias that extend through one or more dielectric layers.

In various embodiments the interposer 304 includes wiring that connect the bond pad I/Os 305 to the through mold via pad I/Os 306. In other embodiments the interposer 304 may be formed as a semiconductor chip having interconnect wiring that connects wire bond pads 305 to through mold via bond pads 306. In various embodiments a semiconductor chip interposer does not have active devices (such as transistors) while in other embodiments it may have active devices (to drive signals between the stacked semiconductor chips and the package level I/Os). More details concerning embodiments of the substrate interposer 304 are described in more detail below.

As observed in FIG. 3d, wire bonds 307 are formed between the wire bond pads on the upper exposed periphery 303 of the stacked semiconductor chips 301 and the wire bond pads 305 on the upper exposed surface of the substrate interposer 304. In embodiments where the stacked chips 301 correspond to memory chips, the collection of wire bonds 307 may correspond to address lines, data lines, control lines, power lines and ground lines.

In one embodiment, a multi-drop memory bus is realized on the substrate interposer 304. Specifically, as is known in the art, a multi-drop memory bus includes address lines and data lines that are electrically connected to a same node. That is, the same address bit or the same data bit of the memory bus is physically connected to the corresponding address bit and data bit of each of the memory devices that are connected to the bus. In this case, the same address bit or the same data bit is connected to each of the memory devices in the chip stack 301 through the wire bonds 307 and the interposer 304 is used to short these same address bits or same data bits together.

For example, in one embodiment, the wire bond pads 305 on the upper surface of the interposer 304 have a large surface area to receive multiple wire bonds 307 (one from each die and one large pad for each same address bit or data bit). In yet other embodiments the wire bond pads 305 may only receive a single wire bond but wire bond pads associated with a same address bit or same data bit are shorted together by the internal wiring of the substrate interposer 304. The shorted node for a same address bit or data bit is then run to an I/O pad 306 for receiving a through mold via. By so doing, the memory bus is exposed for connection to the yet to formed through mold vias and the multi-drop connections are established within the wiring of the interposer 304.

In yet another embodiment, rather than all wire bonds 307 being chip to interposer 304 as suggested by FIG. 3d, chip to chip wire bonds are formed to, e.g., connect a same address/data bit pad of a first chip in the stack to a second, e.g., immediately lower chip in the stack. This “staircasing” of wire bond connections down the edge of the chip stack continues, e.g., to the bottom chip in the stack. A single wire bond is formed from the interposer to the bottom chip pad to complete formation of the multi-drop bus at the interposer pad.

In yet other embodiments the substrate interposer 304 may include some form of electronic signaling translation circuitry to enhance communication between the stacked chips 301 and the package level I/Os. For example, any of termination circuitry, driving circuitry, equalization circuitry, parallel-to-serial and/or serial-to-parallel conversion circuitry may be disposed on the substrate interposer 304 to effectively perform some level of signal processing on the signals that are passed between the stacked chip and the package level I/Os.

As just one example, the package level I/Os may expose a memory bus and the package as a whole may logically operate as if a multi-drop bus exists internally within the package. However, the interposer 304 has circuitry that directs and/or translates the memory bus signals from the package level I/Os to each of the stacked chips as a dedicated (e.g., proprietary) point-to-point link.

As observed in FIG. 3e, after the wire bonds 307 have been formed from the stacked chips 301 to the substrate interposer 304, the stacked chips 301, wire bonds 307 and substrate interposer 304 are encompassed in a mold compound 308 that is formed over the structures on the carrier 302. Here, although only two stacked chip structures are shown on the carrier 302, it is envisioned that a large array of stacked chip structures may be formed on the carrier 302 such that, after the mold compound 308 has been formed over the array of stacked chip structures, a constituted wafer of stacked chips structures will be formed.

As observed in FIG. 3f, openings 309 for through mold vias are formed, e.g., by laser drilling. Here, the bottoms of the openings 309 reach the aforementioned pads 306 of the substrate interposer 304 that are to receive the through mold vias. As observed in FIG. 3g, the openings 309 are filled with metal to complete the formation of the through mold vias 310. As such, the electric interface for the stacked semiconductor chips 301 is now exposed on the upper surface of the mold compound.

As is known in the art, the expense of a through mold via 310 increases with its depth. That is, as the depth of a through mold via increases, there is greater sensitivity with respect to laser drill parameters and/or more time is consumed. Additionally, as the openings 309 become deeper more metal is consumed filling the openings 309. Thus, in various embodiments, the height or thickness of the substrate interposer 304 is deliberately made somewhat large to reduce the depth of the through mold vias 310 and consequently reduce their associated manufacturing costs.

Here, although FIG. 3g shows the height or thickness of the substrate interposer 304 being less than the thickness of two stacked chips and less than 33% of the total chip stack height, in other embodiments the height or thickness of the substrate interposer 304 may be much larger than the height or thickness observed in FIG. 3g. For example, the height or thickness of the interposer 304 may be higher than half the total chip stack height, or between half the total chips stack height and 33% of the total chip stack height. With the understanding that deep through mold vias may not be economically and/or technically feasible, an interposer 304 of respectable thickness can be deliberately used as vehicle for keeping the depths of through mold vias 310 small.

After the through mold vias 310 are formed, as observed in FIG. 3h, a redistribution layer 311 (RDL) is formed on the exposed top surface of the structure observed in FIG. 3g. As is known in the art, a redistribution layer 311 is a multilayer structure that provides one or more layers of interconnect wiring between internal I/Os (in this case, the top faces of the through mold vias 310 and bond pads 313 on the upper surface of the top die in the chip stack) and external package level I/Os (in the case, solder balls 312). Here in order to form the redistribution layer 311, the structure of FIG. 3g may be first coated with a passivation layer (e.g., a nitride) and a polyimide layer.

Then, a layer of photoresist is coated on the polyimide/passivation multilayer and patterned by way of photolithography techniques to expose regions of the polyimide/passivation that reside directly above the upper surfaces of the through mold vias 310 and the I/O pads 313 of the top die of the chip stack. The exposed regions of the polyimide/passivation are then etched to expose the top surfaces of the through mold vias 310 and the I/O pads 313 of the top die of the chip stack.

A layer of copper is then deposited or electroplated onto the exposed upper surfaces of the through mold vias 310 and pads 313. The copper is then patterned with photolithographic techniques to form internal wiring within the redistribution layer 311. Conceivably multiple layers of polyimide and copper wires could be subsequently formed. After the internal wiring layers of the redistribution layer 311 have been formed, a final passivation layer is formed on the structure and etched in certain areas to expose I/O ball pads that were earlier formed on certain ones of the last layer of internal wiring. Package level I/O balls 312 are then placed on the exposed ball pads to complete the structure FIG. 3h.

After the structure of FIG. 3h is formed, the structure is inverted and the carrier 302 is removed (e.g., by heating its low melting point adhesive) as observed in FIG. 3i. After the carrier 302 is removed, the constituted wafer of stacked chip arrays is sawed to singulate the stacked chip structures as observed in FIG. 3j.

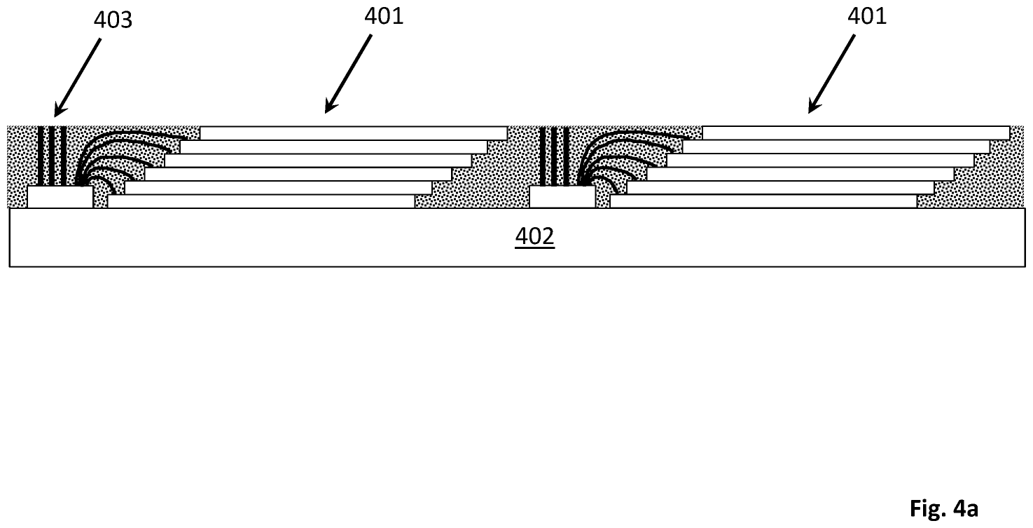

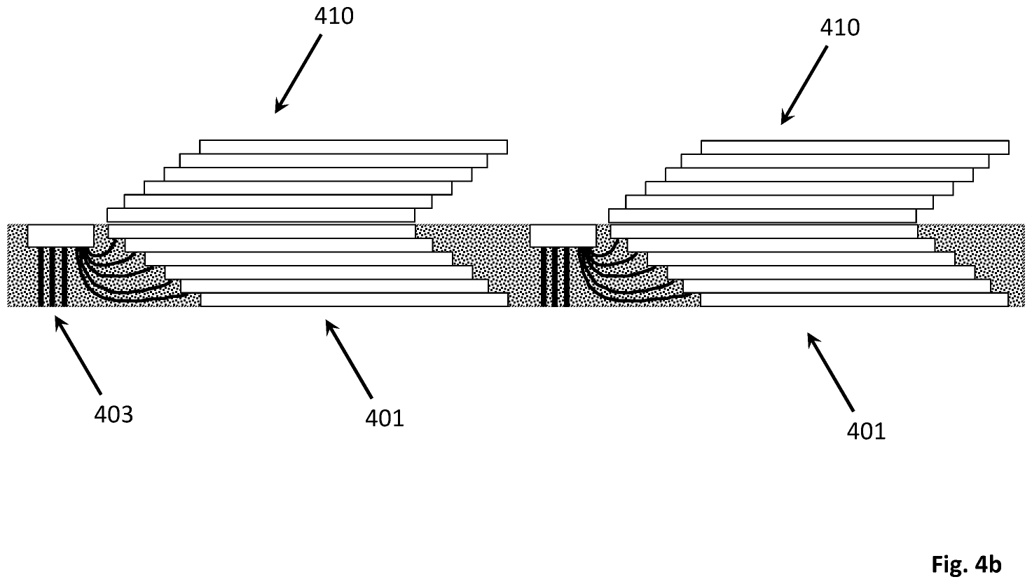

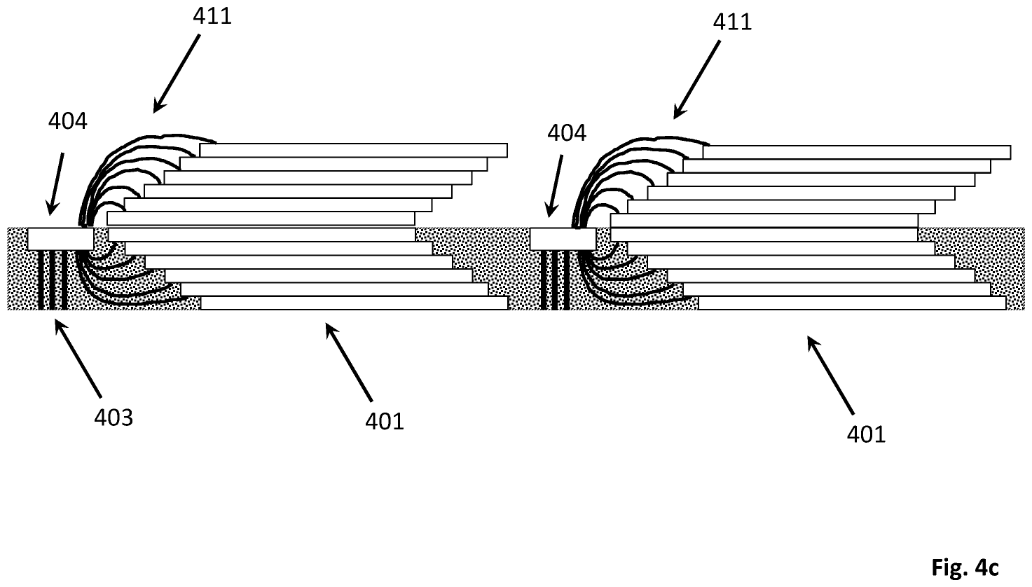

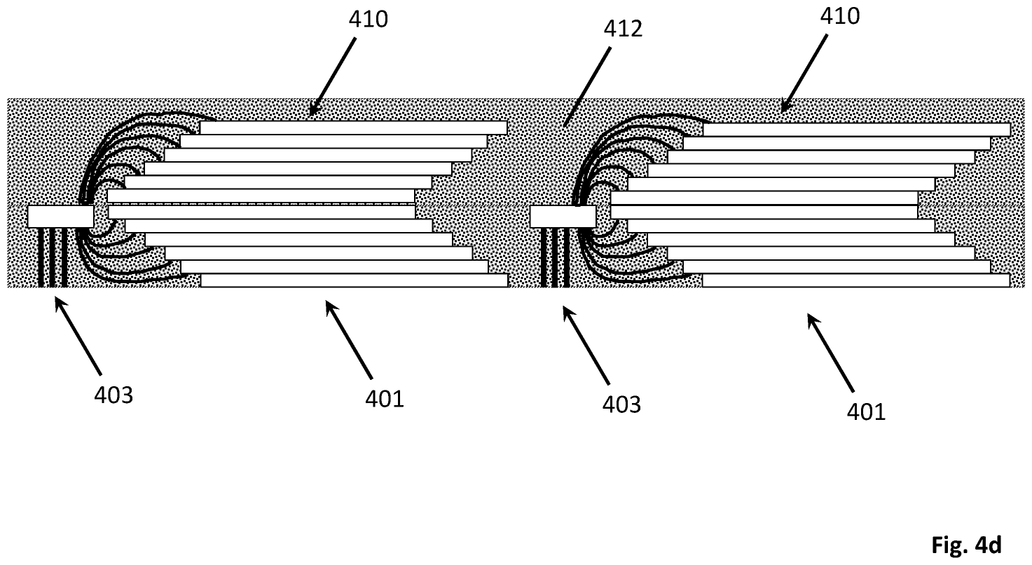

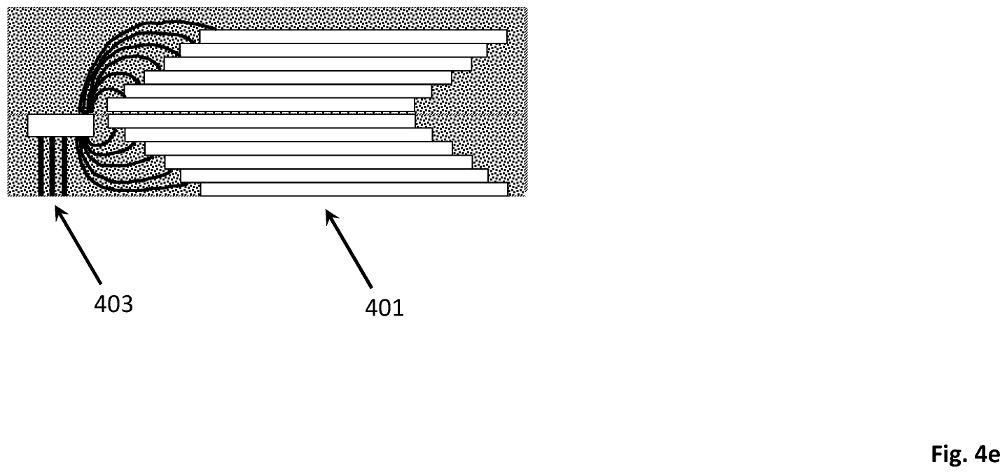

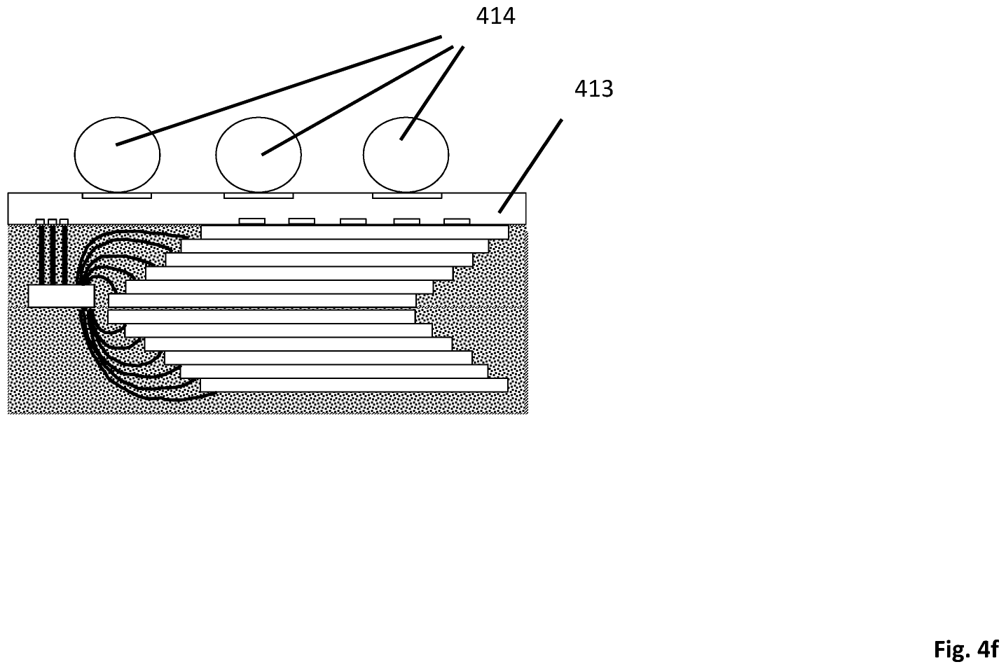

FIGS. 4a through 4e show another method for manufacturing the more aggressive chip stacking structure observed in FIG. 2b. Here, in an embodiment, the method of FIGS. 3a through 3g are performed to form the structure of FIG. 4a. With the structure of FIG. 4a being formed, a wafer of stacked chip structures has been constituted. Additionally through mold vias 403 are formed for the chip stack structure 401

As observed in FIG. 4b the chip stack structures 401 are flipped and the carrier 402 is removed. Additional chip stacks 410 are placed over corresponding chip stacks 401. The additional chips stacks 410 have a lateral offset that is opposite to that of the lower chip stacks 401 so that a zig-zag chip stacking approach is effected. As observed in FIG. 4c, wire bonds are formed from the additional chip stacks to the interposer 404.

As observed in FIG. 4d, a compound mold 412 is formed over the additional chip stacks 410. In an embodiment, the compound mold 412 formed over the additional stacks 410 is thicker than the compound mold formed over the other stacks 401 because, as will be more evident in the immediately following discussion, all of the chips of the additional stacks 410 are wire bonded to the interposer 404 whereas one of the chips of the other stacks 401 (the bottom chip as observed in FIG. 4d) will be directly bonded to an RDL layer or other substrate. As a consequence, the additional chip stacks 410 have more associated wire bond headroom than chip stacks 401.

As observed in FIG. 4e the constituted wafer of both chips stacks 401, 410 is sawed or otherwise cut to singulate the different pairs of stacked chips into individual units. As observed in FIG. 4f, a redistribution layer 413 is formed on the structure of FIG. 4e and package layer I/Os 414 are formed on the redistribution layer 414.

It is pertinent to point out that as an alternative to the embodiments described above the redistribution layer 311, 414 may be replaced with a coreless substrate. Here, a coreless substrate is understood to be composed of alternating layers of patterned dielectric and metal layers. Pads on the surface of the coreless substrate may be designed to mate to the upper surfaces of the through mold vias and the pads on the upper stacked die. For simplicity, the term “substrate” may be construed to mean an RDL, a coreless substrate or any other platform that mechanically integrates the molded chip stacks to the package level I/Os.

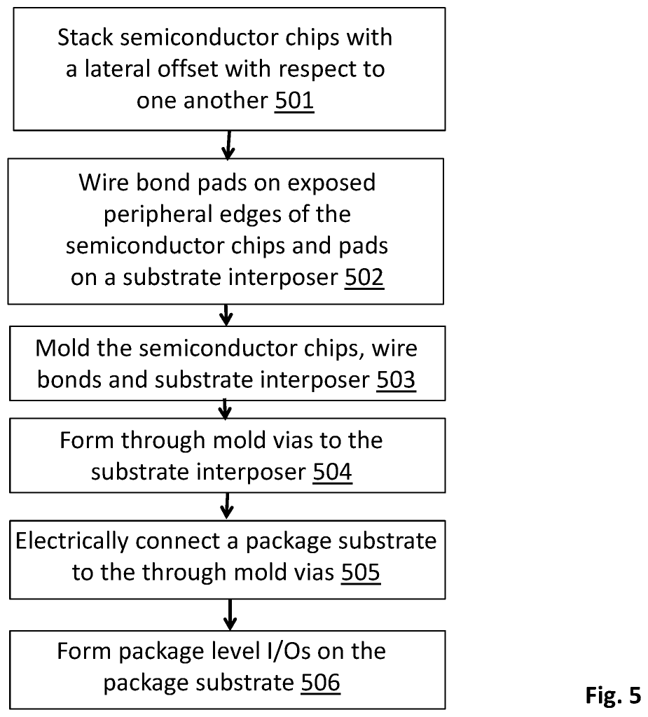

FIG. 5 shows a method of manufacturing a stacked chip semiconductor package as described above. As observed in FIG. 5 the method includes stacking semiconductor chips with a lateral offset with respect to one another 501. The method also includes wire bonding pads on exposed peripheral edges of the semiconductor chips and pads on a substrate interposer 502. The method also includes molding the semiconductor chips, wire bonds and substrate interposer 503. The method also includes forming through mold vias to the substrate interposer 504. The method also includes electrically connecting a package substrate to the through mold vias 504. The method also includes forming package level I/Os on the package substrate 505.

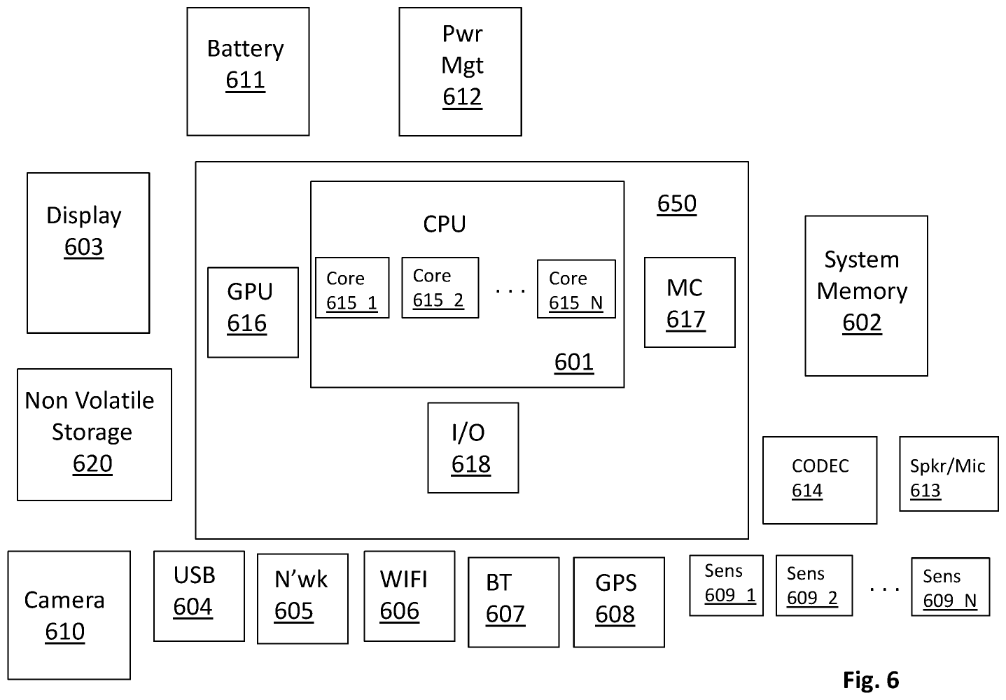

FIG. 6 shows a depiction of an exemplary computing system 600 such as a personal computing system (e.g., desktop or laptop) or a mobile or handheld computing system such as a tablet device or smartphone, or, a larger computing system such as a server computing system. As observed in FIG. 6, the basic computing system may include a central processing unit 601 (which may include, e.g., a plurality of general purpose processing cores and a main memory controller disposed on an applications processor or multi-core processor), system memory 602, a display 603 (e.g., touchscreen, flat-panel), a local wired point-to-point link (e.g., USB) interface 604, various network I/O functions 605 (such as an Ethernet interface and/or cellular modem subsystem), a wireless local area network (e.g., WiFi) interface 606, a wireless point-to-point link (e.g., Bluetooth) interface 607 and a Global Positioning System interface 608, various sensors 609_1 through 609_N (e.g., one or more of a gyroscope, an accelerometer, a magnetometer, a temperature sensor, a pressure sensor, a humidity sensor, etc.), a camera 610, a battery 611, a power management control unit 612, a speaker and microphone 613 and an audio coder/decoder 614.

An applications processor or multi-core processor 650 may include one or more general purpose processing cores 615 within its CPU 601, one or more graphical processing units 616, a memory management function 617 (e.g., a memory controller) and an I/O control function 618. The general purpose processing cores 615 typically execute the operating system and application software of the computing system. The graphics processing units 616 typically execute graphics intensive functions to, e.g., generate graphics information that is presented on the display 603. The memory control function 617 interfaces with the system memory 602. The system memory 602 may be a multi-level system memory such as the multi-level system memory discussed at length above.

The computing system may include a package having stacked chips with wire bonds and a substrate interposer as described above. The package may be implemented, e.g., in mass storage (e.g., as a component of non volatile storage 620 and/or, e.g., in system memory 602.

Each of the touchscreen display 603, the communication interfaces 604-607, the GPS interface 608, the sensors 609, the camera 610, and the speaker/microphone codec 613, 614 all can be viewed as various forms of I/O (input and/or output) relative to the overall computing system including, where appropriate, an integrated peripheral device as well (e.g., the camera 610). Depending on implementation, various ones of these I/O components may be integrated on the applications processor/multi-core processor 650 or may be located off the die or outside the package of the applications processor/multi-core processor 650.

An apparatus has been described. The apparatus includes a semiconductor chip package. The semiconductor chip package includes a plurality of stacked semiconductor chips where the plurality of stacked semiconductor chips are stacked with a lateral offset, and where, the lateral offset exposes first wirebond pads of the plurality of stacked semiconductor chips. The semiconductor chip package also includes a substrate interposer having second wirebond pads. The semiconductor chip package also includes wirebonds connecting the first wirebond pads and the second wirebond pads. The semiconductor chip package also includes a package substrate. The semiconductor chip package also includes vias electrically connected to the substrate interposer and a first surface of the package substrate. The semiconductor chip package also includes package level I/Os on a second surface of the package substrate that is opposite the first surface of the package substrate.

In various embodiments of the apparatus the vias are through mold vias. In various embodiments of the apparatus the substrate interposer includes alternating dielectric and conductive layers. In various embodiments of the apparatus the substrate interposer is composed of a semiconductor chip. In various embodiments of the semiconductor chip interposer the semiconductor chip interposer includes transistors. In various embodiments of the apparatus the package substrate includes a redistribution layer. In various embodiments of the apparatus the package substrate includes a coreless substrate. In various embodiments the semiconductor chip includes a second plurality of stacked semiconductor chips that are stacked with a lateral offset that progresses in a direction opposite to a progression of the lateral offset of the plurality of stacked semiconductor chips. In various embodiments the plurality of stacked semiconductor chips includes memory semiconductor chips. In further embodiments the stacked semiconductor chips include non volatile memory semiconductor chips.

A computing system has been described. The computing system includes a plurality of processing cores; a main memory controller, a network interface; and a semiconductor chip package. The semiconductor chip package includes a plurality of stacked semiconductor chips where the plurality of stacked semiconductor chips are stacked with a lateral offset, and where, the lateral offset exposes first wirebond pads of the plurality of stacked semiconductor chips. The semiconductor chip package also includes a substrate interposer having second wirebond pads. The semiconductor chip package also includes wirebonds connecting the first wirebond pads and the second wirebond pads. The semiconductor chip package also includes a package substrate. The semiconductor chip package also includes vias electrically connected to the substrate interposer and a first surface of the package substrate. The semiconductor chip package also includes package level I/Os on a second surface of the package substrate that is opposite the first surface of the package substrate.

In various embodiments of the computing system the semiconductor chip package is a component in the computing system's mass storage. In various embodiments of the computing system the semiconductor chip package is a component in the computing system's main memory. In various embodiments of the computing system the semiconductor chip package includes a second plurality of stacked semiconductor chips being stacked with a lateral offset that progresses in a different direction than a progression of the lateral offset of the plurality of stacked semiconductor chips. In various embodiments the plurality of stacked semiconductor chips include memory semiconductor chips. In various further embodiments the memory semiconductor chips include non volatile memory semiconductor chips.

A method has been described. The method includes stacking semiconductor chips with a lateral offset with respect to one another. The method also includes wire bonding pads on exposed peripheral edges of the semiconductor chips and pads on a substrate interposer. The method also includes molding the semiconductor chips, wire bonds and substrate interposer. The method also includes forming through mold vias to the substrate interposer. The method also includes electrically connecting a package substrate to the through mold vias. The method also includes forming package level I/Os on the package substrate.

In various embodiments of the method the substrate interposer has a thickness greater than 50% of a height of the stacked semiconductor chips. In various embodiments the method includes stacking more semiconductor chips on the semiconductor chips with a lateral offset that progresses in a different direction than the lateral offset of the semiconductor chips. In various embodiments the method includes wire bonding pads on exposed peripheral edges of the more semiconductor chips and more pads on the substrate interposer.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a semiconductor chip package comprising:
a) a plurality of stacked semiconductor chips, the plurality of stacked semiconductor chips being stacked with a lateral offset, wherein, the lateral offset exposes first wirebond pads of the plurality of stacked semiconductor chips;
b) a substrate interposer comprising second wirebond pads;
c) wirebonds connecting the first wirebond pads and the second wirebond pads;
d) a package substrate;
e) vias electrically connected to the substrate interposer and a first surface of the package substrate; and,
f) package level I/Os on a second surface of the package substrate that is opposite the first surface of the package substrate.

2. The apparatus of claim 1 wherein the vias are through mold vias.

3. The apparatus of claim 1 wherein the substrate interposer is comprised of alternating dielectric and conductive layers.

4. The apparatus of claim 1 wherein the substrate interposer is comprised of a semiconductor chip.

5. The apparatus of claim 4 wherein the semiconductor chip comprises transistors.

6. The apparatus of claim 1 wherein the package substrate comprises a redistribution layer.

7. The apparatus of claim 1 wherein the package substrate comprises a coreless substrate.

8. The apparatus of claim 1 further comprising a second plurality of stacked semiconductor chips being stacked with a lateral offset that progresses in a direction opposite to a progression of the lateral offset of the plurality of stacked semiconductor chips.

9. The apparatus of claim 1 wherein the plurality of stacked semiconductor chips comprises memory semiconductor chips.

10. The apparatus of claim 1 wherein the memory semiconductor chips comprise non volatile memory semiconductor chips.

11. A computing system, comprising:
a plurality of processing cores;
a main memory controller;
a network interface; and,
a semiconductor chip package comprising:
a) a plurality of stacked semiconductor chips, the plurality of stacked semiconductor chips being stacked with a lateral offset, wherein, the lateral offset exposes first wirebond pads of the plurality of stacked semiconductor chips;
b) a substrate interposer comprising second wirebond pads;
c) wirebonds connecting the first wirebond pads and the second wirebond pads;
d) a package substrate;
e) vias electrically connected to the substrate interposer and a first surface of the package substrate; and,
f) package level I/Os on a second surface of the package substrate that is opposite the first surface of the package substrate.

12. The computing system of claim 11 wherein the semiconductor chip package is a component in the computing system's mass storage.

13. The computing system of claim 11 wherein the semiconductor chip package is a component in the computing system's main memory.

14. The computing system of claim 11 further comprising a second plurality of stacked semiconductor chips being stacked with a lateral offset that progresses in a different direction than a progression of the lateral offset of the plurality of stacked semiconductor chips.

15. The computing system of claim 11 wherein the plurality of stacked semiconductor chips comprises memory semiconductor chips.

16. The computing system of claim 11 wherein the memory semiconductor chips comprise non volatile memory semiconductor chips.

17. A method, comprising:
stacking semiconductor chips with a lateral offset with respect to one another;
wire bonding pads on exposed peripheral edges of the semiconductor chips and pads on a substrate interposer;
molding the semiconductor chips, wire bonds and substrate interposer;
forming through mold vias to the substrate interposer;
electrically connecting a package substrate to the through mold vias; and,
forming package level I/Os on the package substrate.

18. The method of claim 17 wherein the substrate interposer has a thickness greater than 50% of a height of the stacked semiconductor chips.

19. The method of claim 17 further comprising stacking more semiconductor chips on the semiconductor chips with a lateral offset that progresses in a different direction than the lateral offset of the semiconductor chips.

20. The method of claim 19 further comprising wire bonding pads on exposed peripheral edges of the more semiconductor chips and more pads on the substrate interposer.
